(19) United States
(12) Patent Application Publication
(10) Pub. No.: US 2026/0326365 A1
(43) Pub. Date: Oct. 22, 2026

(54) IMPRINT METHOD, ARTICLE MANUFACTURING METHOD, AND MOLDING APPARATUS

(71) Applicant: CANON KABUSHIKI KAISHA, Tokyo (JP)

(72) Inventor: SARI ITO, Tochigi (JP)

(21) Appl. No.: 19/574,563

(22) Filed: Mar. 23, 2026

(30) Foreign Application Priority Data
Apr. 21, 2025 (JP) 2025-069305

(51) Int. Cl. B29C 59/02; B29C 59/00

(52) U.S. Cl. CPC B29C 59/022; B29C 59/002

(57) ABSTRACT

An imprint method for forming a pattern by contacting an imprint material that has been supplied on a plurality of shot regions on a substrate with a pattern region of a mold includes aligning the mold in a position that has been offset in a planar direction of the substrate in a direction away from a position of an adjacent shot region that is adjacent to a target shot region on which the pattern has already been formed before contacting the imprint material that has been supplied on the target shot region on which the pattern will be formed with the mold; and contacting the mold that has been aligned with the imprint material that has been supplied on the target shot region.

### FIELD OF THE TECHNOLOGY

The present disclosure relates to an imprint method, an article manufacturing method, and a molding apparatus.

### DESCRIPTION OF THE RELATED ART

Imprinting technologies are known as technologies for manufacturing semiconductor devices, and the like. An imprinting technology is a technology that uses a mold on which a pattern has been formed, and forms a pattern on an imprint material that has been supplied onto a substrate by pressing the mold onto the imprint material. For example, according to imprinting technologies, it is possible to form microstructures of a nanometer order on a substrate.

There are cases in which a drop-on-demand method in which the imprint material is applied for each shot of the nanoimprint is applied as the method for supplying the imprint material. This is because it is possible to make the residual layer thickness uniform and to increase the transfer accuracy by locally adjusting the resin amount according to the pattern density and shape of the mold.

In the imprint apparatus, it is preferable that when the mold is contacted with the imprint material on the substrate, the relative positional relationship between the substrate and the mold is correctly adjusted, and initial alignment is performed. If this adjustment is performed incorrectly, provisionally, it is possible that the pattern that has been formed on the substrate and the mold will collide with one another, thereby damaging the substrate and/or the mold, and causing transfer defects.

Japanese Patent Laid-Open No. 2016-076626 discloses a method in which before contacting the mold and the imprint material on the substrate, initial alignment is performed based on information for a drive amount for a correction unit during global alignment, and alignment for a different shot region in which imprinting was previously performed, and after having contacted the mold and the imprint material on the substrate, alignment is performed by driving the correction unit.

However, in the prior art technology, there arises the need to eliminate exposure of the undercoat from between adjacent shot regions that have not been taken into consideration. In a case in which there are regions in which there is no imprint material (in which the undercoat is exposed), the substrate will be eroded by etching processing, and this becomes the cause of a deterioration of the uniformity of the etching in the vicinity of the pattern borders. In addition, there are also cases in which deterioration of the uniformity of the CMP (chemical mechanical polishing) that is performed after this also occurs. Therefore, there is a need to decrease the exposure of the undercoat of adjacent shot regions.

In the method of the prior art technology, errors can occur during the initial alignment in both the plus and minus directions on one axis for the target position. This means that in a case in which an alignment mark and the mold have been designed with the gap between the shot regions as zero, this can interfere with the patterns that have already been formed. The risk of the substrate and/or the mold being damaged, and of transfer defects increases due to the collision of patterns that have been formed on the substrate and the mold.

### SUMMARY

The present disclosure is directed to provide an imprinting method that reduces damage to patterns that have been formed on a substrate and/or a mold, as well as transfer defects for the patterns.

According to an aspect of the present disclosure, an imprinting method for forming a pattern by contacting an imprint material that has been supplied on a plurality of shot regions on a substrate with a pattern region of a mold includes aligning the mold in a position that has been offset in a planar direction of the substrate in a direction away from a position of an adjacent shot region that is adjacent to a target shot region on which the pattern has already been formed before contacting the imprint material that has been supplied on the target shot region on which the pattern will be formed with the mold; and contacting the mold that has been aligned with the imprint material that has been supplied on the target shot region.

Features of the present disclosure will become apparent from the following description of embodiments with reference to the attached drawings. The following description of the embodiments is described by way of example.

### BRIEF DESCRIPTION OF THE DRAWINGS

FIGS. 1A and 1B are diagrams for explaining a subject of an embodiment.

FIG. 2 is a diagram showing a configuration of an imprint apparatus according to the present embodiment.

FIG. 3 is a flowchart for imprint processing in the imprint apparatus that was shown in FIG. 2.

FIGS. 4A-4C are diagrams relating to a mold that is used during imprint processing in the present embodiment.

FIGS. 5A-5D are explanatory diagrams for imprint processing in the present embodiment.

FIGS. 6A, and 6B are diagrams of shot regions at the time of imprinting in the present embodiment.

FIG. 7 is a diagram for explaining an article manufacturing method.

### DESCRIPTION OF THE EMBODIMENTS

Below, embodiments of the present disclosure will be explained in detail with reference to the attached drawings. Note that the following embodiments do not limit the disclosure according to the scope of the claims. Although a plurality of features is disclosed in the embodiments, it is not the case that all of this plurality of features are necessary components of the present disclosure, and in addition, a plurality of features may also be arbitrarily combined.

### Subject in the present embodiment

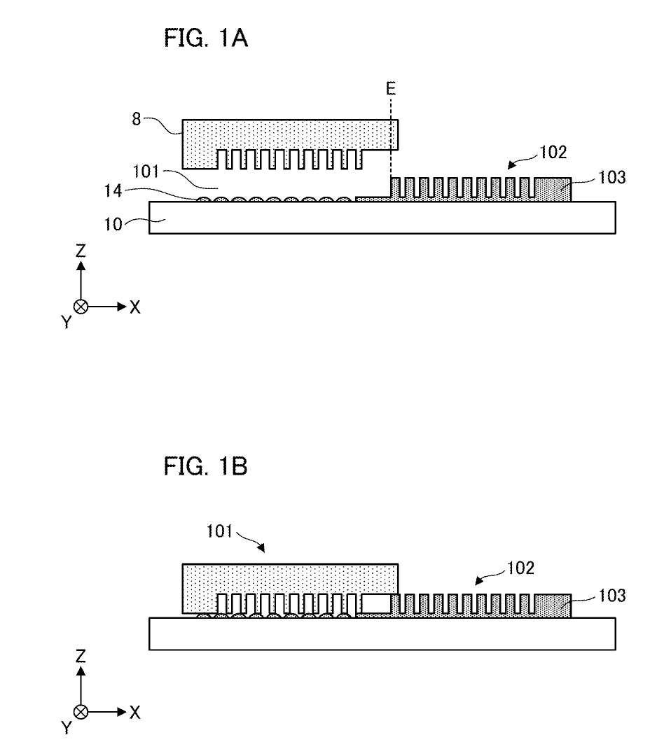

FIGS. 1A, and 1B are diagrams explaining a subject according to the present embodiment. FIG. 1A shows a cross-section view of when a mold 8 that is in a target shot region 101 of a substrate 10 has been initially aligned with a position according to a feature edge E of a transferred pattern 103 that has already been formed on an adjacent shot region 102. In this state, if pushing the mold 8 by moving it downward from the initial position (in the -Z direction) is attempted, as is shown in FIG. 1B, the mold 8 will contact/collide with the feature edge E of the transferred pattern that has already been formed on the adjacent shot region 102. The substrate 10 and/or the mold 8 are thereby damaged, and transfer defects thereby occur for the pattern.

### Imprint apparatus

The imprint apparatus is an apparatus that forms a pattern of a cured substance on which a relief pattern of the mold has been transferred by contacting the mold with the imprint material that has been supplied on the substrate and supplying energy for use in curing to the imprint material. For example, an imprint apparatus supplies the imprint material onto the substrate, and cures this imprint material in a state in which a mold on which a relief pattern has been formed has been contacted with the imprint material on the substrate.

In addition, it is possible to transfer the pattern of the mold onto the imprint material on the substrate by widening the gap between the mold and the substrate and detaching (separating) the mold from the cured imprint material. Such series processing is referred to as imprint processing, and is performed for each of a plurality of shot regions on the substrate. That is, in a case in which imprint processing is performed for each of the plurality of shot regions on one substrate, the imprint processing is repeatedly performed for the exact number of shot regions on this one substrate.

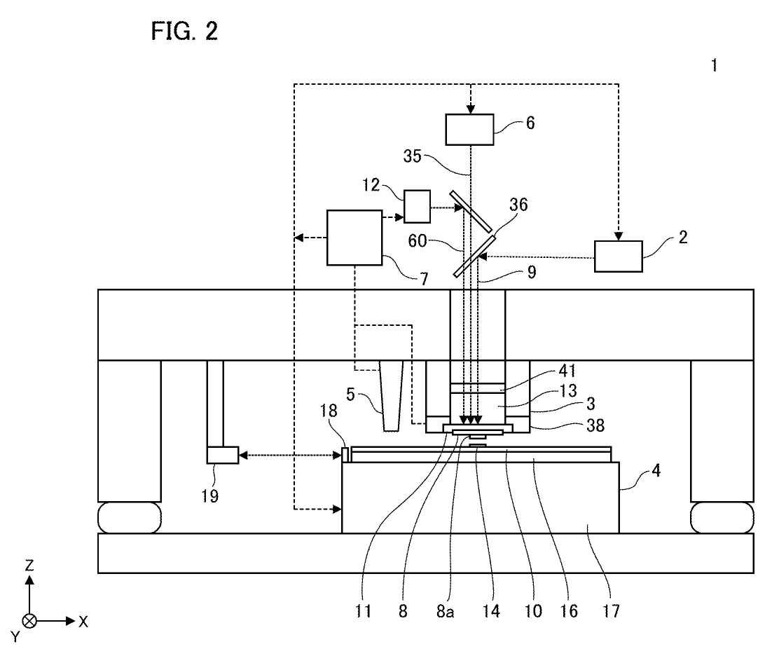

FIG. 2 is a diagram showing a configuration of an imprint apparatus (molding apparatus) 1 according to the present embodiment. The configuration of the imprint apparatus 1 will be explained using FIG. 2. In this context, the surface on which a substrate 10 is disposed is made an XY surface, and a direction that is orthogonal to this surface is made a Z direction, and each axis is determined as is shown in FIG. 2.

The imprint apparatus 1 is an apparatus that contacts an imprint material 14 that has been supplied on the substrate 10 with the mold 8, and applies energy thereto for use in curing the imprint material 14, and thereby forms a pattern of a cured substance onto which a relief pattern of the mold 8 has been transferred. The mold 8 is also referred to as a model, a template, and an original. The imprint apparatus 1 of FIG. 2 is used in the manufacturing of a device such as a semiconductor device, and the like that serves as an article. In this context, an imprint apparatus 1 that uses a photo-curing method will be explained.

The imprint apparatus 1 is provided with a mold holding unit 3 (imprinting head) that holds and moves the mold 8, a substrate holding unit 4 (stage) that holds and moves the substrate 10, and a discharge mechanism 5 (imprint material supplying unit) that disposes the imprint material 14 onto the substrate. In addition, the imprint apparatus 1 is also provided with an irradiation system 2 (a curing unit) that irradiates a light 9 such as an ultraviolet light and the like that cures the imprint material 14, an image capturing unit 6 that captures images of the contact state between the mold and the imprint material 14 by irradiating a light 35, and a control unit 7 that controls operations of the imprint apparatus 1. Furthermore, the imprint apparatus 1 is also provided with a detector 12 that detects a mark that has been formed on the mold 8 and a mark that has been formed on the substrate 10.

The substrate holding unit 4 is provided with a substrate chuck 16 that holds the substrate 10, and a stage drive mechanism 17 that controls a position of the substrate 10 in relation to at least the two axes of the X axis direction and the Y axis direction in an XYZ coordinate system. In addition, the substrate holding unit 4 is provided with, on a side surface thereof, a plurality of reference mirrors 18 corresponding to each direction of X, Y, Z, ωx, ωy, and ωz.

In relation to this, the imprint apparatus 1 is provided with a plurality of laser interferometers 19 (distance measuring devices) that measure a position of the substrate holding unit 4 by irradiating each of these reference mirrors 18 with a beam. The laser interferometers 19 measure the position of the substrate holding unit 4, and the control unit 7 executes alignment control for the substrate 10 (the substrate holding unit 4) based on the measurement value from this time. The imprint apparatus 1 may also measure the position of the substrate holding unit 4 by using an encoder instead of the reference mirrors 18 and laser interferometers 19.

The mold holding unit 3 is moved in the up-and-down direction (the direction of the Z axis) by a mold drive mechanism 38 (actuator) that has been provided to the mold holding unit 3 in a state in which the mold 8 is held by a mold chuck 11. A pattern region 8a of the mold 8 is contacted with (pressed onto) the imprint material 14 by the mold holding unit 3 being moved in the downward direction (-Z direction) by the mold drive mechanism 38. A reverse pattern of the relief pattern that will be formed on the substrate is formed on the pattern region 8a of the mold 8 that is used in the imprint apparatus 1. In the following explanation, although a case will be explained in which a mesa unit of the mold 8 is the pattern region 8a, this may also be a flat unit on which a pattern has not been formed.

After the imprint material has been cured, the pattern region 8a for the mold 8 is separated (released) from the imprint material that has been cured by the mold holding unit 3 being moved in the upward direction (+Z direction) by the mold drive mechanism 38. The pushing and releasing may also be performed by moving the substrate holding unit 4 in the Z direction instead of moving the mold holding unit 3, and may also be performed by moving both the mold holding unit 3 and the substrate holding unit 4 relative to each other. That is, the mold holding unit 3 functions as a drive unit that drives the mold and the substrate holding unit 4 functions as a drive unit that drives the substrate.

Furthermore, the mold holding unit 3 may also be provided with a space 13 that has been separated by a light transmitting member 41 (for example, a quartz plate) and the mold 8, and it is possible to deform the mold 8 at the time of pressing and the time of release by adjusting the pressure within the space 13. For example, it is possible to contact the pattern region 8a and the imprint material 14 by changing the mold 8 into a convex shape in relation to the substrate 10 by increasing the pressure inside of the space 13 at the time of pressing.

The detector 12 is able to detect a mark that has been formed on the mold 8 and a mark that has been formed on the substrate 10 using a detection light 60. The imprint apparatus 1 is able to find the relative positions of the mold 8 and the substrate 10 based on the detection results of the detector 12, and it is possible to align the mold 8 and the substrate 10 by moving at least one of the mold 8 and the substrate 10.

The image capturing unit 6 is configured (disposed) so as to include the pattern region 8a of the mold 8 that has been held by the mold holding unit 4 in the visual field thereof, and acquires images by capturing images of at least the mold 8 and the substrate 10. The image capturing unit 6 is a camera (spread camera) that observes the contact state of the mold 8 and the imprint material 14 on the substrate 10, and is able to confirm the state on the substrate 10.

The control unit 7 includes a CPU, a memory, and the like, and controls the operations of each of the mechanisms of the imprint apparatus 1 in order to form patterns on the plurality of shot regions that have been formed on the substrate 10. In addition, the control unit 7 can also be configured so as to control the mold holding unit 3, the substrate holding unit 4, the discharge mechanism 5, the light irradiating system 2 (curing unit), the image capturing unit 6, and the detector 12. The control unit 7 may also be provided within the imprint apparatus 1, and may also be disposed in a different location than the imprint apparatus 1 and remotely control the imprint apparatus 1. That is, the control unit 7 controls the supply unit and the drive unit.

As the imprint material 14, an imprint material (also referred to as resin in an uncured state) that is cured by the application thereto of energy for use in curing is used. As the energy for use in curing, electromagnetic waves, and the like are used. As the electromagnetic waves, for example, there is light such as infrared light, visible light, ultraviolet light, and the like for which the wavelength thereof is selected in a range from equal to above 10nm and equal to or less than 1mm.

The imprint material 14 is a composition that is cured by the irradiation of light, and alternatively a composition that is cured by the application of heat. From among these, photo-imprint materials that are cured by light include at least a polymerizable composition and a photopolymerization initiator, and may also include a non-polymerizable composition and a solvent according to necessity. The non-polymerizable composition is at least one type of composition selected from the group consisting of a sensitizer, a hydrogen donor, an internal mold release agent, a surfactant, an antioxidant, a polymer component, and the like.

The imprint material 14 is applied to the substrate, by a liquid jet head and the like with an ink jet method of the discharge mechanism 5, in a droplet form, and conversely an island form and a membrane form that have been made by a plurality of droplets connecting. The viscosity of the imprint material (viscosity at 25˚C) is for example, equal to or greater than 1 mPa·s, and less than or equal to 100 mPa·s.

Glass, a ceramic material, metal, a semiconductor, resin, and the like are used as the substrate 10, and members consisting of a different material than the substrate may also be formed on the surface of the substrate according to necessity. Specifically, a silicon wafer, a compound semiconductor wafer, quartz glass, and the like are used as the substrate 10.

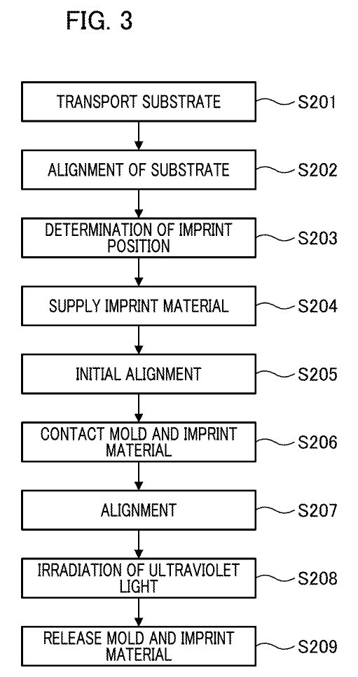

Next, the imprint method (imprint processing) according to the imprint apparatus 1 will be explained with reference to FIG. 3. FIG. 3 is a flowchart with respect to the basic imprint processing. First, the substrate 10 is loaded and fixed onto the substrate holding unit 4 by a substrate transport apparatus (not shown) (S201). Next, the alignment marks on the substrate 10 are sequentially detected and the position of the substrate 10 is detected with a high degree of precision by the detector 12 while appropriately changing the position of the substrate 10 by driving the stage drive mechanism 17 (S202). The control unit 7 calculates each transfer coordinate from the results thereof, and consecutively forms the pattern per each specific shot region based on these calculation results (step and repeat).

Next, the flow of the pattern formation for one specific shot region will be explained. First, the control unit 7 determines the shot region of the substrate 10 to which the imprint material 14 should be supplied. In addition, alignment of the determined shot region underneath a discharge opening of the discharge mechanism 5 is performed by the stage drive mechanism 17 (S203). After this, the discharge mechanism 5 supplies the imprint material 14 to the shot region that was aligned during S203 (S204).

Next, the control unit 7 moves and performs initial alignment for the substrate 10 such that the shot region is positioned in a pressing position directly underneath the pattern region 8a of the mold 8 by the stage drive mechanism 17 (S205). Next, the control unit 7 aligns the pattern region 8a with the substrate-side pattern of the shot region, and executes magnification correction and the like for the pattern region 8a using a magnification correction mechanism. After this, as a pressing step, the mold drive mechanism 38 is driven, the pattern region 8a is made to contact the imprint material 14 on the shot region, and pressing is performed (S206). The imprint material 14 fills the relief pattern on the pattern region 8a by this contacting and pressing.

Note that the control unit 7 is able to perform a determination of completion of pressing using a load sensor that has been disposed within the mold holding unit 3. In a case in which imprinting is being performed on a substrate on which there is already a pattern, the positions of the pattern region 8a of the mold and the pattern of the shot region on the substrate are made to match by alignment (S207). In this state, as the curing step, the light irradiation system 2 irradiates the light 9, which is, for example, an ultraviolet light, from a rear surface (upper surface) of the mold 8 for a predetermined time, and the imprint material 14 is cured by the light 9 that has passed through the mold 8. (S208).

In addition, after the imprint material 14 has been cured, as a releasing step, the control unit 7 re-drives the mold drive mechanism 38, and separates the pattern region 8a from the substrate 10 (S209). A 3-dimensional imprint pattern that has copied the relief pattern of the pattern region 8a is thereby formed on the surface of the shot region on the substrate 10. It is possible for the imprint apparatus 1 to form a plurality of resin patterns on one substrate 10 by executing such a series of imprint processes a plurality of times while changing the shot region by driving the substrate holding unit 4.

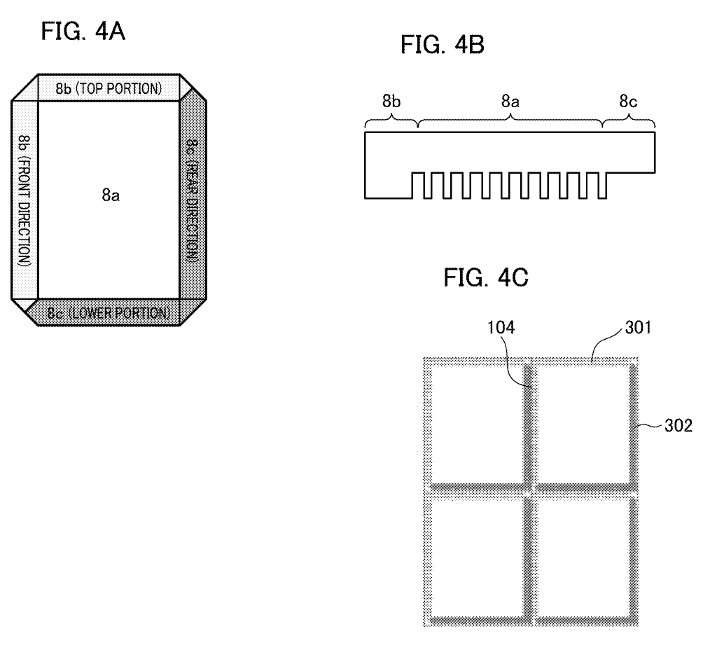

Next, the processes after the initial alignment (S205) from among the above-described imprint method will be explained. FIGS. 4A-4C show perspective diagrams of the mold 8, which can be used in order to reduce exposure of the undercoat between adjacent shot regions. FIG. 4A is a perspective diagram of the mold 8 as seen from above, and FIG. 4B is a cross-section diagram that can be obtained when the mold 8 has been cleaved in half.

As is shown in FIG. 4B, the pattern region 8a of the mold 8 is interposed between a region 8b (leading edge) that has the tallest height within the pattern of the mold 8, and a recessed region 8c (a trailing edge) in a position more toward the inside of the substrate than the position of the tallest height in the pattern. Note that the leading edge 8b is also referred to as a non-recessed region according to the labeling of the trailing edge 8c as a recessed region. Note that in the following explanation, the pattern region 8a, the leading edge 8b, and the trailing edge 8c are referred to as the mesa unit of the mold 8.

That is, the leading edge 8b corresponds to a first region that has been formed at the tallest height from within the pattern region, and the trailing edge 8c corresponds to a second region that has been formed at a height that is lower than the tallest height.

The leading edge 8b forms a pattern edge with the same height as the residual layer, and the trailing edge 8c forms a pattern edge with a height that is the same as the feature height. The leading edge 8b is one portion of an edge region that includes the upper area and the front direction area in FIG. 4A. The trailing edge 8c is a portion of an edge region that includes the lower area and the rear direction area of FIG. 4A. Therefore, the pattern region 8a is surrounded by the leading edge 8b and the trailing edge 8c. That is, the first region (the leading edge 8b), and the second region (the trailing edge 8c) are formed on at least one pair of edges facing the shot region.

The frontal area and the rear area are opposing (facing) sides via the pattern region 8a. The upper area and the lower area are opposing sides (facing) via the pattern region. This may also be configured by any one of the areas from among the combination of the frontal area and the rear area, and the upper area and the lower area. The leading edge 8b and the trailing edge 8c are disposed based on the order in which imprinting will be performed on the substrate.

In order to reduce the exposure of the undercoat between adjacent shot regions, the control unit 7 aligns the mold 8 to the substrate 10 such that the shot region is adjacent to and/or overlaps with a shot region that is one or more shot regions before the current shot region (a shot region on which a pattern has already been formed). The leading edge 8b may also overlap with a future shot region (in a case in which a future shot region exists), and the trailing edge 8c may also overlap with a previous shot region (in a case in which a previous shot region exists).

FIG. 4C shows a perspective diagram of a shot region at the time of imprinting as seen from above. In FIG. 4C, an imprinting step is assumed in which imprinting is performed by positioning a plurality of square-shaped imprint regions in an array shape that has been segmented by shot borders 104. In addition, from among the two edges that interpose one corner of a square-shaped imprint region, the two edges that consist of the pattern edge that is formed by the leading edge 8b, which consists of the upper area and the forward area of the mold 8 that was shown in FIG. 4A, are made a first border 301 (represented by light hatching). In addition, from among the two sides that interpose one corner of the square-shaped imprint region, the two edges that consist of the pattern edge that is formed by the trailing edge 8c, which consists of the lower area and the rear area of the mold 8 that was shown in FIG. 4A, are made a second border 302 (represented with dense hatching).

In the present embodiment, imprint processing is performed such that the second border 302 of the target shot region corresponds to the first border 301 of an adjacent shot region on which imprinting has already been performed. By repeating this, pattern formation that reduces the exposure of the undercoat between adjacent shot regions becomes possible across all imprint regions using one application requirement. As an array forming method that realizes this, for example, a case in which movement is constantly performed in the forward direction in each of the rows and columns, and the like is given as an example. That is, the second region (the trailing edge 8c) is disposed so as to be adjacent to and/or overlap with an adjacent shot region.

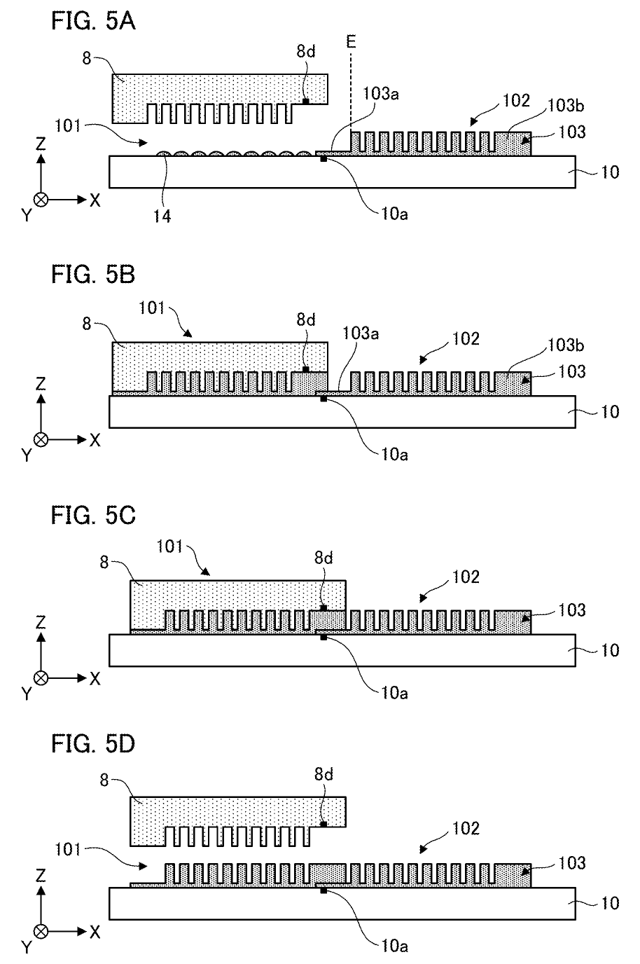

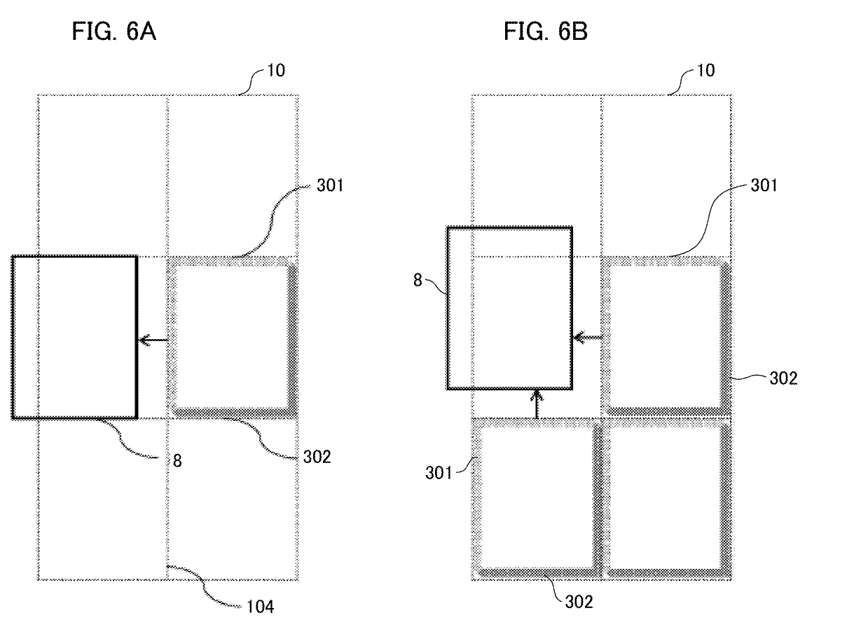

FIGS. 5A-5D show an imprint method in which the exposure of the undercoat between shot regions is eliminated, and the pattern that has been formed on the substrate does not contact and/or collide with the mold 8. FIGS. 6A and 6B are plan views explaining the imprint method of FIGS. 5A-5D.

In FIG. 5A, the imprint material 14 is disposed on the substrate 10. A transferred pattern 103 for which the imprint processing was completed one or more imprint processing times before the current imprint processing is formed on a shot region 102 that is adjacent to the target shot region 101 on which imprint processing will be performed. The edge 103a of the transferred pattern 103 is formed by the leading edge 8b of the mold 8, and the edge 103b of the transferred pattern 103 is formed by the trailing edge 8c of the mold 8.

From among the edges of the transferred pattern 103, the edge 103a, which is in proximity with the target shot region, is an edge that has been formed by the leading edge 8b of the mold 8. The edge 103a spreads out until the shot border 104 (FIGS. 6A and 6B). With respect to the placement position of the imprint material 14 in the target shot region 101, an optimal position is determined according to the pressing distance and force of the mold 8, the amount of imprint material 14 that is disposed on the substrate, and properties thereof such as viscosity and the like.

FIG. 5A shows a state of a cross-section for when the mold 8 has been initially aligned in the target shot region 101 such that the mold 8 is disposed in a state in which there is an offset between the adjacent shot region 102 in the opposite direction (the direction away from the adjacent shot region). It is possible to initially align (S205) the mold 8 in the target shot region 101 in a position that does not overlap with the edge E of a feature of the transferred pattern 103 that has already been formed on an adjacent shot region 102.

The offset amount may be 100 nm or more, and the offset amount may also be 200 nm or more. In actuality, the offset amount is dependent on the efficiency of the initial positioning. The greatest value for the offset amount corresponds to the measurement range for a mark unit 8d of the mold 8. As one example, the largest value for the offset amount can be made 250 nm, and preferably 500 nm. The larger that the offset amount becomes, the smaller that the risk of the mold 8 contacting/colliding with the edge E of the feature of the transferred pattern 103 that has already been formed on the adjacent shot region 102 becomes. In contrast, the smaller that the offset amount becomes, the less time is necessary for the alignment, and therefore, this is beneficial from the point of throughput. Therefore, the offset amount may also be determined from a balance between the risk of contact/collision between the mold 8 and the transferred pattern 103 and the throughput.

FIGS. 6A, and 6B show perspective diagrams of the substrate 10 and the mold 8 as seen from above for when the mold 8 has been initially aligned in the target shot region 101 so as to be disposed in a state in which there is an offset in the opposite direction with the adjacent shot region 102. The direction of the offset is made so as to become the opposite direction (direction away from) the adjacent shot region on which imprinting has already been performed.

In FIG. 6A, the transferred pattern that has already been formed on the adjacent shot region only exists in the direction of the rear area of the trailing edge 8c of the mold 8 in the target shot region. In this case, the direction of the offset that has been represented with an arrow is made so as to become the opposite side as the direction of the rear area of at least the trailing edge 8c.

In FIG. 6B, the transferred pattern that has already been formed on the adjacent shot region exists in both directions of the direction of the rear area and the direction of the lower area of the trailing edge 8c of the mold 8 in the target shot region. In this case, the direction of the offset that has been shown by an arrow is made so as to become the opposite side of the direction of both the rear area and the lower area of the trailing edge 8c.

That is, the initial alignment that was explained in the above-described FIGS. 5A, 6A, and 6B, corresponds to an aligning step in which the alignment of the mold is performed in a position that is offset from the direction away from the position of the adjacent shot region that is adjacent to the target shot region on which the pattern has already been formed in the direction that is parallel to the substrate surface. As was explained in the flowchart of FIG. 3, this step is performed before the imprint material that has been supplied on top of the target region on which the pattern will be performed is contacted with the mold.

The mold 8 contacts the pattern region 8a of the mold 8 with the imprint material by moving in the downward direction (-Z direction) from the initial position. As is shown in FIG. 5B, it is possible to begin contact with the imprint material 14 without the mold 8 contacting/colliding with the edge of the transferred pattern 103 that has already been formed on the adjacent shot region 102. It is preferable that the pattern edge that is formed by the leading edge 8b and the trailing edge 8c does not protrude from the mold 8. That is, FIG. 5B corresponds to a contacting step in which a mold for which alignment has been performed by the aligning step is contacted with an imprint material that has been supplied on the target shot region.

If initial alignment is performed for the mold 8 in a state in which there is an offset in the opposite direction of the adjacent shot region 102, as is shown in FIG. 5B, this becomes a state in which the mark unit 8d of the mold 8 and a mark unit 10a of the substrate 10 are misaligned. In a case in which the mark unit 8d and the mark unit 10a are misaligned, both of the mark units are read by the detecting light 60 from the detector 12, the mark units are aligned by moving the mold 8 and the substrate 10, and alignment is performed. That is, this alignment corresponds to a moving step in which after the mold has been contacted with the imprint material that has been supplied onto the target shot region by the contacting step, at least one from among the mold and the substrate are moved such that the mold is brought closer to the adjacent shot region. In addition, the mark unit 8d corresponds to an alignment mark that has been formed on the mold, and the mark unit 10a corresponds to an alignment mark that has been formed on the target shot region.

The direction of movement during the alignment is the direction in which the offset amount for during the initial alignment becomes smaller. At the time of the completion of the alignment, as is shown in FIG. 5C, the mark unit 8d of the mold 8 and the mark unit 10a of the substrate 10 have reached the same position as seen from the Z direction. After this, as is shown in FIG. 5D, the mold 8 is released after the imprint material 14 has been cured. It is thereby possible to form a pattern such that the areas between shot regions are adjacent to each other and/or overlap with each other via the shot borders 104.

Note that even in imprinting processing in which there is no alignment of the mark unit 8d of the mold 8 and the mark unit 10a of the substrate 10, in the same manner, the initial positioning of the mold may also be performed in a state in which there is an offset in the direction away from the adjacent shot region 102. After this, movement may be performed in the direction in which the offset amount becomes smaller. By having the leading edge 8b and the trailing edge 8c overlap, it is possible to eliminate the exposure of the undercoat between shot regions by allowing a certain extent of positional error while also avoiding interference with the already existing pattern even without precise positioning.

According to the present embodiment, it is possible to eliminate exposure of the undercoat between adjacent shot regions, and to decrease damage to the pattern that has been formed on the substrate and/or the mold as well as transfer defects in the pattern. In addition, by using a mold that has a leading edge and a trailing edge, it is also possible to allow for minor errors in the positioning for filling the gaps between the shot regions.

### Embodiment of Article Manufacturing Method

There are cases in which the pattern in the cured substance that has been formed using the imprint machine is used permanently in at least a portion of each type of article, and there are cases in which the pattern in the cured substance that has been formed using the imprint machine is used temporarily when manufacturing each type of article. The article is an electronic circuit element, an optical element, a MEMS, a recording element, a sensor, a mold, and the like. As the electronic circuit element, there are volatile and nonvolatile semiconductor memories such as a DRAM, an SRAM, a flash memory, and an MRAM, semiconductor elements such as an LSI, a CCD, an image sensor, an FPGA, and the like. As the mold, there is a mold for use in imprinting, and the like.

The pattern in the cured substance may be used as is as a configurational member of at least one part of the above described articles, and may also be temporarily used as a resist mask. The resist mask is discarded after etching, ion implantation, and the like are performed during a working process for the substrate.

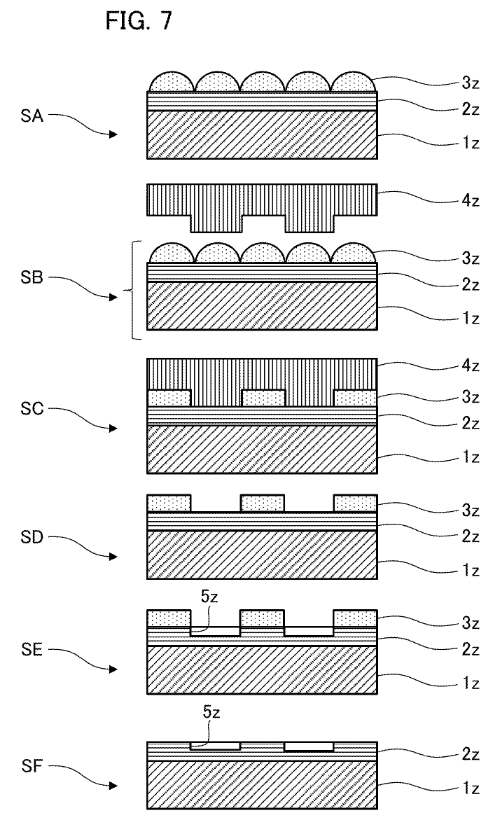

Next, the specific manufacturing method for the article will be explained with reference to FIG. 7. First, as is shown in the step SA, a substrate 1z such as a silicon wafer and the like on which a workpiece 2z such as an insulating material and the like has been formed on the surface thereof is prepared, and following this, a composition 3z is applied to the surface of the workpiece 2z using an ink jet method and the like. In this context, a state is shown in which the composition 3z, which is in the form of a plurality of droplets, has been applied onto the substrate.

Next, as is shown in the step SB, a side on which a relief pattern has been formed on a mold 4z for use in imprinting is made to face toward the composition 3z on the substrate. In addition, as is shown in the step SC, the substrate 1z onto which the composition 3z has been applied and the mold 4z and the substrate 1z are contacted, and pressure is applied. The composition 3z fills in the gaps between the mold 4z and the workpiece 2z. When light is irradiated through the mold 4z in this state to serve as energy for use in curing, the composition 3z is cured.

Next, as is shown in the step SD, after the composition 3z has been cured, when the mold 4z and the substrate 1z are separated, a pattern of the cured substance of the composition 3z is formed on top of the substrate 1z. This pattern of the cured substance is a shape in which the concave portions of the mold correspond to the convex portions of the cured substance, and the convex portions of the mold correspond to the concave portions of the cured substance, that is, it becomes such that the relief pattern of the mold 4z has been transferred onto the composition 3z.

Next, as is shown in the step SE, when etching is performed using the pattern of the cured substance as a etch-resistant mask, it becomes such that from among the surface of the workpiece 2z, the portions in which there is no cured substance and the portions in which there is a thin residual layer of the cured substance are removed, and these regions become grooves 5z. In addition, as is shown in the process SF, when the pattern of the cured substance is removed, it is possible to obtain a product on which the grooves 5z have been formed on the surface of the workpiece 2z. In this context, although the pattern of the cured substance has been removed, for example, this may also be used as a membrane for use as insulation between layers that are included in semiconductor elements and the like, that is, as a configurational member of a product, without performing this removal after the working has been performed.

### Other Embodiments

Although above, favorable embodiments of the present disclosure have been explained, the present disclosure is not limited to these embodiments, and various changes and alterations are possible within the scope of the gist thereof. It is also possible to realize the present disclosure using processing in which a program that realizes one or more functions of the above-described embodiments is provided to a system, and an apparatus via a network and a storage medium, and one or more processors in a computer of this system and apparatus read out and execute the program. In addition, it is also possible to realize the present disclosure using a circuit (for example, an ASIC) that realizes one or more of the functions of the above-described embodiments.

According to the present disclosure, it is possible to reduce damage to a pattern that has been formed on a substrate, and/ or to a mold, as well as transfer defects in the pattern.

Embodiment(s) of the present disclosure can also be realized by a computer of a system or apparatus that reads out and executes computer executable instructions (e.g., one or more programs) recorded on a storage medium (which may also be referred to more fully as a 'non-transitory computer-readable storage medium') to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)TM), a flash memory device, a memory card, and the like.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-069305, filed Apr. 21, 2025, which is hereby incorporated by reference herein in its entirety.

What is claimed is:

1. An imprint method for forming a pattern by contacting an imprint material that has been supplied on a plurality of shot regions on a substrate with a pattern region of a mold, the imprint method comprising:
aligning the mold in a position that has been offset in a planar direction of the substrate in a direction away from a position of an adjacent shot region that is adjacent to a target shot region on which the pattern has already been formed before contacting the imprint material that has been supplied on the target shot region on which the pattern will be formed with the mold; and
contacting the mold that has been aligned with the imprint material that has been supplied on the target shot region.

2. The imprint method according to claim 1, further comprising:
moving at least one of the mold and the substrate so as to bring the mold closer to the adjacent shot region after the mold has been contacted with the imprint material that has been supplied on the target shot region.

3. The imprint method according to claim 2,
wherein the moving includes aligning an alignment mark that has been formed on the mold and an alignment mark that has been formed on the target shot region.

4. The imprint method according to claim 1,
wherein a first region that has been formed at the tallest height within the pattern region and a second region that has been formed at a height that is shorter than the tallest height are formed, respectively, on at least one pair of opposing sides of the mold.

5. The imprint method according to claim 4,
wherein the second region is positioned so as to be adjacent to and/or overlap with the adjacent shot region.

6. A method for manufacturing an article, the method comprising:
forming a pattern on a substrate according to an imprint method for forming the pattern by contacting an imprint material that has been supplied on a plurality of shot regions on the substrate with a pattern region of a mold, the imprint method including:
aligning the mold in a position that has been offset in a planar direction of the substrate in a direction away from a position of an adjacent shot region that is adjacent to a target shot region on which the pattern has already been formed before contacting the imprint material that has been supplied on the target shot region on which the pattern will be formed with the mold; and
contacting the mold that has been aligned with the imprint material that has been supplied on the target shot region;
processing the substrate on which the pattern has been formed; and
manufacturing an article from the substrate that has been processed.

7. A molding apparatus for forming a pattern by contacting an imprint material that has been supplied on a plurality of shot regions on a substrate with a pattern region of a mold, the molding apparatus comprising:
a supply unit configured to supply the imprint material onto the substrate;
a drive unit configured to drive the substrate and the mold;
at least one memory storing instructions; and
at least one processor executing the stored instructions causing the molding apparatus to:
before driving the drive unit so as to contact the imprint material that has been supplied on top of a target shot region on which the pattern will be formed with the mold, cause the drive unit to drive the mold to a position that has been offset in a planar direction of the substrate in a direction away from a position of an adjacent shot region that is adjacent to the target shot region on which the pattern has already been formed; and
drive the drive unit so as to contact the mold with the imprint material that has been supplied on the target shot region.
